(19) United States
(12) Patent Application Publication
(10) Pub. No.: US 2010/0133643 A1
(43) Pub. Date: Jun. 3, 2010

(54) IMAGE SENSOR PIXEL AND METHOD THEREOF

(75) Inventor: Cheol Soo Park, Jeju-si (KR)

Correspondence Address: CANTOR COLBURN, LLP, 20 Church Street, 22nd Floor, Hartford, CT, 06103, US

(73) Assignees: Cheol Soo Park, Jeju-si (KR); SILICONFILE TECHNOLOGIES INC., Seoul (KR)

(21) Appl. No.: 11/917,979

(22) PCT Filed: Jun. 14, 2006
(86) PCT No.: PCT/KR06/02273

§ 371 Date: Dec. 18, 2007

(30) Foreign Application Priority Data
Jun. 20, 2005 (KR) 10-2005-0052993

(51) Int. Cl. H01L 31/0352; H01L 31/18; H01L 21/20

(52) U.S. Cl. 257/461; 438/57; 438/478; 257/E31.038; 257/E21.09

(57) ABSTRACT

A method of manufacturing a pixel of an image sensor including a protruded photodiode capable of improving photosensitivity and reducing crosstalk between neighboring pixels and a pixel of an image sensor formed using the method are provided. The pixel of the semiconductor image sensor includes a protrudedly shaped photodiode on a surface of a semiconductor substrate. A surface area of the photodiode with respect to a surface area of the image sensor pixel increases to improve photosensitivity, and a microlens is not needed due to the improvement of the fill factor. In addition, the crosstalk of neighboring pixels can be removed.

### TECHNICAL FIELD

The present invention relates to a structure of an image sensor and a method thereof, and more particularly, to an active pixel of a 4-transistor complementary metal oxide semiconductor (CMOS) image sensor.

### BACKGROUND ART

An image sensor is a device for capturing an image using a characteristic of a semiconductor device sensitive to an external energy (e.g. photon). Light emitted from each object in the natural world has a characteristic energy value such as a wavelength. A pixel of the image sensor senses the light emitted from each subject and converts the sensed light into an electrical value. This pixel of the image sensor may be 4-transistor CMOS active pixel.

FIG. 1 is a circuit diagram of an image sensor including four transistors 110 to 140 and a diode 190. Operations of the image sensor circuit are as followed. In a first reset section, light collected on the photodiode is converted into an electric signal after the photodiode is reset by a RX signal and a TX signal to transmit the electric signal to an output node Vout via a transmission transistor 110, a driver transistor 130, and a selection transistor 140.

FIG. 2 shows a plane structure of the aforementioned 4-transistor image sensor, and FIG. 3 shows a cross section of FIG. 2.

Here, reference numerals 110 to 140 of four transistors constituting the active pixel are the same as those of four transistors of FIG. 1.

A node between the transmission transistor 110 and a reset transistor 120 is connected to a gate of the driver transistor 130 by a metal layer 125 through a contact region.

A p-well layer 150 is prepared for the photodiode to form according to a manufacturing sequence.

Particularly, the image sensor using the CMOS technology uses an epitaxially grown semiconductor substrate in which the leak current is small to improve sensor characteristics.

A PDN layer 160 is formed by performing ion implantation of N-type impurities into a cathode of the photodiode 190. A PDP layer 180 is formed by the ion implantation of P-type impurities into an anode of the photodiode 190. An area where the PDN layer 160 overlaps the PDP layer 180 to form a PN junction is an area of the photodiode 190.

A PDC layer 185 is used for connecting the photodiode to the source region of the transmission transistor 110.

On the other hand, as technologies of the semiconductor have been developed, a size of the image sensor pixel decreases, and the size of the photodiode also decreases. Since the number of overlapping between insulating layers and metal wiring layers on the semiconductor substrate increases, a distance from the surface of the pixel to the photodiode becomes large to reduce the amount of the light collected on the photodiode of the pixel and deteriorate image quality of the image sensor.

As shown in FIG. 4, the conventional method enables the incident light entered into the image sensor to be collected by forming a convex lens type microlens 420 on an uppermost layer over a color filter 410 of the formed pixel to increase an amount of light which reaches the photodiode.

Generally, it is known that the larger the area of the photodiode is the higher the image quality is. Fill factor is the area which the photodiode occupies over the entire area of the pixel. The characteristic of the pixel is estimated by the fill factor. As shown in FIG. 2, in the conventional active pixel, the photodiode and the transistors have to be arranged on one plane, and therefore, the fill factor is only 6-16%. Accordingly, photosensitivity is deteriorated, the distance between the neighboring pixels decreases, and crosstalk increases, which in turn generates much noises.

### DISCLOSURE OF INVENTION

### Technical Problem

In order to solve the aforementioned problems, an object of the present invention is to provide an image sensor pixel having a protruded shape on a semiconductor substrate and a method thereof to increase an area of a photodiode within a restricted area of the image sensor pixel.

Another object of the present invention is to provide an image sensor pixel so as to minimize crosstalk between neighboring pixels.

Another object of the present invention is to provide an image sensor capable of forming a relatively large photodiode within a restricted area of a pixel to obtain a high sensitivity and a high resolution.

Another object of the present invention is to provide an image sensor pixel without a microlens.

Another object of the present invention is to provide an electronic device mounting the image sensor according to the present invention to obtain an economical efficiency.

### Technical Solution

According to an aspect of the present invention, there is provided a pixel of a semiconductor image sensor including a photodiode having a protruded shape on a surface of a semiconductor substrate.

According to another aspect of the present invention, there is provided a pixel of a semiconductor image sensor including: a photodiode formed under a surface of a semiconductor substrate; and a photodiode having a protruded shape on the surface of the semiconductor substrate.

According to another aspect of the present invention, there is provided a pixel of a semiconductor image sensor including: a first photodiode formed under a surface of a semiconductor substrate; and a second photodiode having a protruded shape on the surface of the semiconductor substrate, which is located over the first photodiode.

According to another aspect of the present invention, there is provided a method of manufacturing a pixel of an image sensor, the method including: (a) forming a first region having an opposite type with respect to a semiconductor substrate by performing an ion implantation into the substrate; and (b) forming an epitaxial layer having a predetermined thickness on the substrate.

According to another aspect of the present invention, there is provided a method of manufacturing a pixel of an image sensor, the method including: forming a first region having an opposite type with respect to a semiconductor substrate by performing ion implantation into the substrate; forming an epitaxial layer having a predetermined thickness on the substrate; and implanting ions into the epitaxial layer.

### BRIEF DESCRIPTION OF THE DRAWINGS

FIG. 1 is a circuit diagram of a CMOS image sensor having a 4-TR structure;

FIG. 2 is a plan layout of a conventional CMOS image sensor;

FIG. 3 is a cross section of a conventional CMOS image sensor;

FIG. 4 is a cross sectional view of the image sensor when completing the production of the image sensor of FIG. 3;

FIG. 5 is a top plan view showing some layers of the pixel according to the present invention;

FIG. 6 is a top plan view showing other layers of the pixel according to the present invention;

FIG. 7 is a top plan view emphasizing only other metal layers and connection parts thereof in the pixel according to the present invention;

FIG. 8 is a cross section for explaining a part of manufacturing processes of a photodiode of the pixel according to the present invention;

FIG. 9 is a cross section for explaining another part of manufacturing processes of the photodiode of the pixel according to the present invention;

FIG. 10 is another directional cross section for explaining a part of manufacturing processes of a photodiode of the pixel according to the present invention; and

FIG. 11 is a cross section showing photodiodes of neighboring pixels according to the present invention.

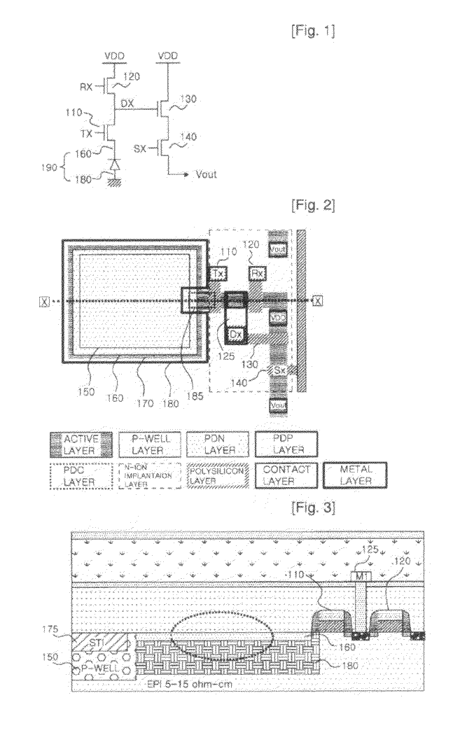

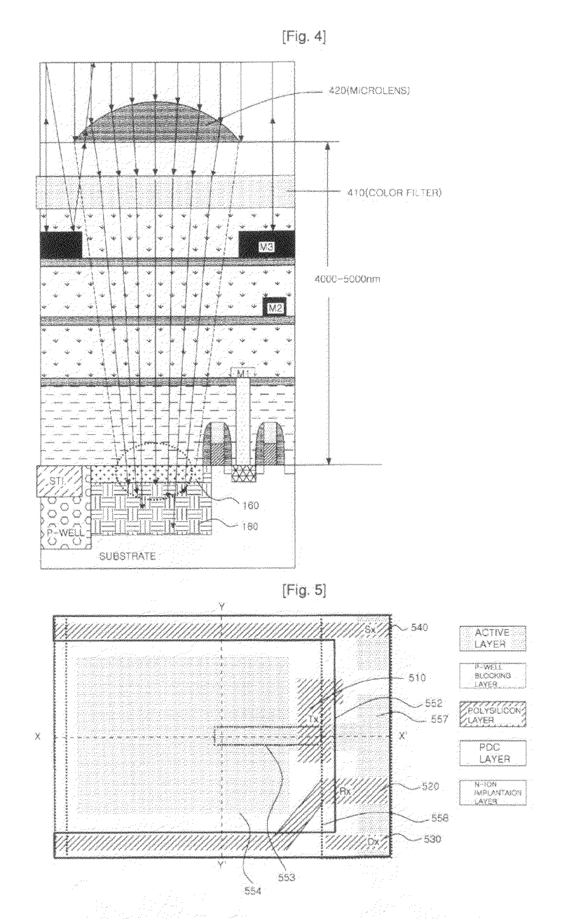

### BEST MODE FOR CARRYING OUT THE INVENTION

The attached drawings for illustrating exemplary embodiments of the present invention are referred to in order to gain a sufficient understanding of the present invention, the merits thereof, and the objectives accomplished by the implementation of the present invention.

Hereinafter, the present invention will be described in detail by explaining exemplary embodiments of the invention with reference to the attached drawings. Like reference numerals in the drawings denote like elements.

FIG. 5 is a top plan view showing a pixel, and particularly, showing some layers of transistors and a photodiode. Four transistors 510 to 540 denote a transmission transistor 510, a reset transistor 520, a driver transistor 530, and a selection transistor 540, respectively. Gate inputs of these transistors are represented by Tx, Rx, Dx, and Sx, respectively.

A P-well layer 552 is a layer preventing P-ion implantation into the layer, and an active layer 554 is a region where an anode is formed.

A PDC layer 553 is a layer electrically connecting a cathode of the photodiode to a source of the transmission transistor 510.

An active layer 557 is a region where a source or drain of a transistor is formed.

An N-ion implantation layer 558 is a layer in which the ion implantation is performed so that the transistors which are active elements of the pixel are N-channel types.

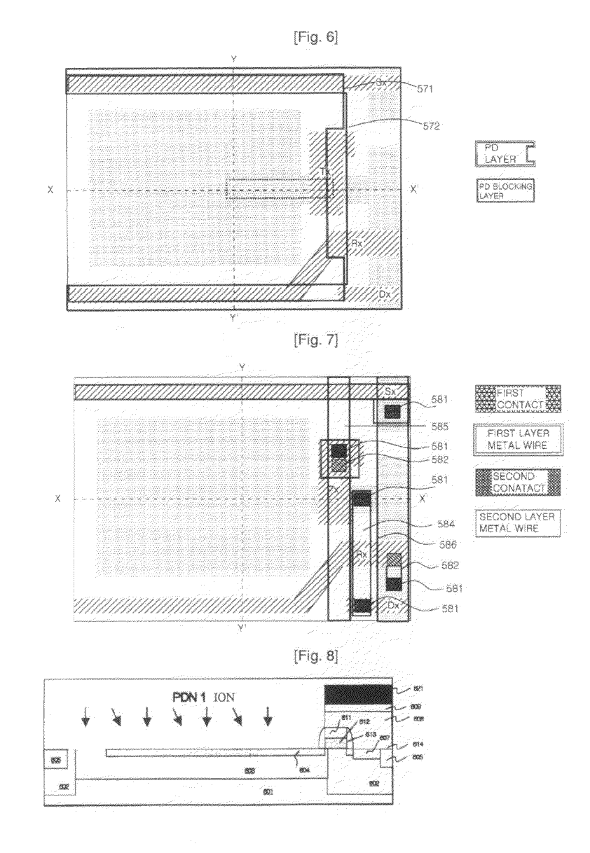

FIG. 6 shows a structure where two layers are additionally stacked on the structure of FIG. 5. A PD layer 571 defines a layer where the photodiode is formed. A photodiode region is formed by etching method using a photomask of the PD layer 571. A PD blocking layer 572 is used for forming two photodiodes.

FIG. 7 is a top plan view emphasizing metal layers. A first contact 581 is a region representing a contact with a metal wire of a first layer, and a second contact 582 is a region representing a contact with a metal wire of a second layer. One metal wire 585 of the second layer is used for applying a transmission signal Tx to a gate of the transmission transistor 510. Another metal wire 586 of the second layer is used for transmitting a source voltage to the pixel. A metal wire 584 of the first layer is used to connect a drain node of the transmission transistor to a gate of the driver transistor 530.

FIG. 5 to FIG. 7 separately show various layers stacked in processes of manufacturing a semiconductor device for the convenience of description. In practice, it should be noted that the semiconductor device is constructed by properly combining the layers shown in FIG. 5 to FIG. 7.

FIG. 8 and FIG. 9 are cross sections of FIG. 7 taken along X-X′. Referring to FIG. 8 and FIG. 9, a method of manufacturing a pixel according to an embodiment of the present invention is described.

FIG. 8 is a cross section for explaining a method of manufacturing a photodiode of the pixel according to the present invention. Preferably, a semiconductor substrate 601 used for manufacturing an image sensor according to the present invention is a P-type, and has a resistance of 10-15 ohm-cm. An epitaxially grown substrate in which the leak current is small has been used for the image sensor in the past, and however, a sufficiently large fill factor can be obtained according to the present invention without using the epitaxially grown substrate.

After a P-well 602 is formed from the semiconductor substrate 601, gates 611 and 612 and a side wall 613 are formed. Then, a region 604 where the transmission transistor is connected to the photodiode is formed by the ion implantation. Subsequently, a drain region 607 is formed by the ion implantation. A nitride layer 614 then coats the gates 611 and 612, and a floating insulating layer such as a PSG film 608 containing phosphor coats the nitride layer 614.

At this time, a BSG film containing boron together with the PSG film may coat the nitride layer 614 to form a double film 608. In addition, planarization may be continuously performed using a known chemical mechanical polishing (CMP) after forming the PSG film or the PSG-BSB double film.

A trench 605 is formed next to the drain 607 of the transmission transistor to be insulated from the neighboring pixel.

An oxide layer 609 is formed on the BSG layer 608. A photoresist layer 621 used for forming the photodiode region is deposited and etched using a photodiode forming mask.

Next, a first N-type region 603 is formed under the photodiode connection region 604 by the ion implantation. Theoretically, a region between the first N-type region 603 and the P-type substrate 601 and a region between the first N-type region 603 and the P-well 602 become PN-junctions. A region where charge carriers caused by irradiation are generated is the entire first N-type region 603.

Next, as shown in FIG. 9, an epitaxial layer 633 is grown from the first N-type region 603, and ions of N-type impurities are implanted into the epitaxial layer 633. This epitaxial layer is a second N-type region. This ion implantation may be omitted according to circumstances. Ions of P-type impurities are implanted into an upper part 631 of the epitaxial layer 633 to convert the upper part 631 to a first P-type region. After the implantation process, the second N-type region 633 and the first P-type region 631 form a second diode 633 different from a first diode 603, and therefore effectively two diodes exist in one pixel.

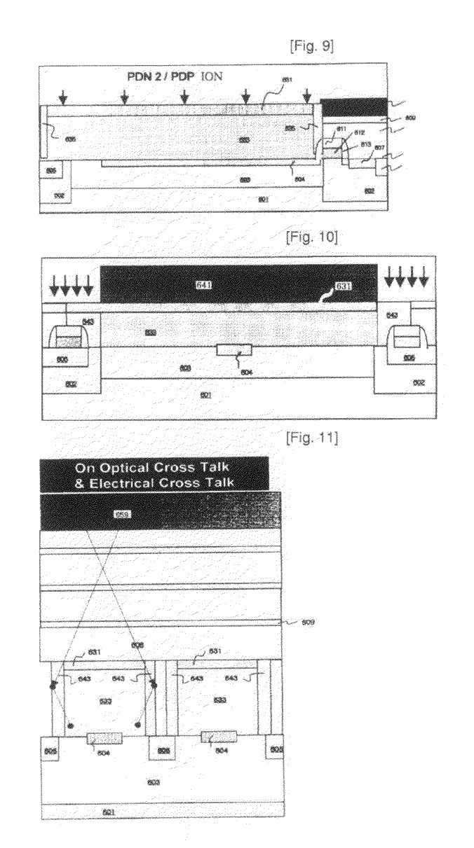

FIG. 10 is a cross section of FIG. 7 taken along Y-Y′. After a process of FIG. 10, the second P-type region 643 is formed by the ion implantation of the P-type impurities into the region except the photodiode region using a mask layer 641 defining the photodiode region. The PN junction area of the second diode increases due to the second P-type region 643, and accordingly, the region where the charge carriers are generated by the incident light increases to generate more intensive electric signals without crosstalk.

FIG. 11 is a cross section showing photodiodes of neighboring pixels according to the present invention. Referring to FIG. 11, another advantage of the present invention is evidently shown. A perpendicular incident light of lights incident through a color filter 659 generates charge carriers in a second photodiode 633. However, differently from the conventional photodiode, even slantly incident lights are totally reflected by the insulating film 643 and introduced into the inside of the second photodiode to maximize the light collecting efficiency. As described above, the insulating film may be a BSG layer, PSG layer, or composite layer including PSG and BSG layers.

While the present invention has been particularly shown and described with reference to exemplary embodiments thereof, it will be understood by those of ordinary skill in the art that various changes in form and details may be made therein without departing from the spirit and scope of the present invention as defined by the following claims.

### INDUSTRIAL APPLICABILITY

According to the present invention, a surface area of a photodiode increases to improve a fill factor and photo-sensitivity.

In addition, the light collecting efficiency is improved, and therefore a microlens is unnecessary to provide an economical efficiency.

Accordingly, crosstalk between neighboring pixels is minimized by a photodiode having a protruded structure to manufacture an image sensor having improved efficiency.

1. A pixel of a semiconductor image sensor comprising a photodiode having a protruded shape on a surface of a semiconductor substrate.

2. A pixel of a semiconductor image sensor comprising:
a photodiode formed under a surface of a semiconductor substrate; and
a photodiode having a protruded shape on the surface of the semiconductor substrate.

3. The pixel of claim 1 or 2, wherein the photodiode having the protruded shape is formed by epitaxial growth.

4. The pixel of claim 1, wherein the photodiode formed under the surface of the semiconductor substrate and the photodiode having the protruded shape on the surface of the semiconductor substrate undergo an ion implantation process

5. The pixel of claim 3, wherein the pixel is formed by the epitaxial growth and undergoes the ion implantation process.

6. The pixel of claim 3, the epitaxial growth starts from the photodiode formed under the surface of the semiconductor substrate.

7. A pixel of a semiconductor image sensor comprising:
a first photodiode formed under a surface of a semiconductor substrate; and
a second photodiode having a protruded shape on the surface of the semiconductor substrate, which is located over the first photodiode.

8. The pixel of claim 1, 2, or 7, wherein the semiconductor substrate comprises:
a well; and
a trench separation region having a thickness thinner than that of the well.

9. A method of manufacturing a pixel of an image sensor, the method comprising:
(a) forming a first region having an opposite type with respect to a semiconductor substrate by performing ion implantation into the substrate; and
(b) forming an epitaxial layer having a predetermined thickness on the substrate.

10. A method of manufacturing a pixel of an image sensor, the method comprising:
forming a first region having an opposite type with respect to a semiconductor substrate by performing ion implantation into the substrate;
forming an epitaxial layer having a predetermined thickness on the substrate; and
implanting ions into the epitaxial layer.

11. The method of claim 9 or 10, wherein (b) starts from the first region.

12. The method of claim 9 or 10, further comprising:
(a) forming a well having an opposite type with respect to a semiconductor substrate on the substrate; and
(b) forming a trench region shallower than the well.
